(19) United States
(12) Patent Application Publication
(10) Pub. No.: US 2026/0282780 A1
(43) Pub. Date: Sep. 17, 2026

(54) CYCLIC PROCESS AND METHOD TO PROVIDE UNIFORM ETCHING OF MATERIAL FORMED WITHIN FEATURES HAVING DIFFERENT CRITICAL DIMENSION (CD)

(71) Applicant: Tokyo Electron Limited, Tokyo (JP)

(72) Inventors: Shan Hu, Albany, NY (US); Sangita Kumari, Albany, NY (US); Karthikeyan Pillai, Albany, NY (US); Osamu Miyahara, Albany, NY (US)

(21) Appl. No.: 19/078,248

(22) Filed: Mar. 12, 2025

(51) Int. Cl. H01L 21/3065; H01L 21/311

(52) U.S. Cl. CPC H10P 50/242; H10P 50/285

(57) ABSTRACT

Embodiments of processes and methods are disclosed to provide uniform etching of material within features (such as, e.g., trenches, holes, slits, etc.) having different critical dimension (CD). In the present disclosure, a cyclic process is used to provide uniform etching of the material within the features, regardless of CD. The cyclic process generally includes: (a) a surface modification step to chemically modify an exposed surface of the material and form a modified surface layer on the material, and (b) a removal step to selectively remove the modified surface layer without etching an underlying unmodified surface of the material. By using such a process, the embodiments disclosed herein provide “CD-independent etching” of material formed within features of different CD and enable an even thickness of the material to be removed from the features, regardless of CD.

### RELATED ART

The present application is related to commonly assigned U.S. Pat. No. 12,100,599, entitled “Wet Etch Process and Method to Provide Uniform Etching of Material Formed within Features Having Different Critical Dimension (CD),” issued Sep. 24, 2024; the entirety of which is incorporated by reference.

### BACKGROUND

The present disclosure relates to the processing of substrates. In particular, it provides etch processes and methods of etching that provide uniform etching of material within features having different critical dimensions (CD).

Semiconductor device formation typically involves a series of manufacturing techniques related to the formation, patterning, and removal of layers of material on a substrate. During routine semiconductor fabrication, various materials formed on a substrate may be removed by patterned etching, chemical-mechanical polishing, as well as other techniques. A variety of techniques are known for etching layers on a substrate, including plasma-based or vapor-phase etching (otherwise referred to as dry etching) and liquid based etching (otherwise referred to as wet etching).

Wet etching generally involves dispensing a chemical solution over the surface of a substrate or immersing the substrate in the chemical solution. The chemical solution (otherwise referred to as an etch solution) often contains a solvent and etchant chemical(s) designed to react with materials on the substrate surface and promote dissolution of the reaction products. As a result of exposure of the substrate surface to the etch solution, material is removed from the substrate. The composition and temperature of the etch solution may be controlled to control the etch rate, specificity, and residual material on the surface of the substrate post-etch.

As geometries of substrate structures continue to shrink and the types of structures evolve, the challenges of etching substrates have increased. One such challenge is CD-dependent etching of material formed within narrow features (such as, e.g., trenches, holes, slits, etc.). In many applications, features having different critical dimensions (CDs) may be formed across a substrate. A wide variety of etch processes can be used to remove material from the features, including both wet and dry etch processes. When a wet etch process is utilized to remove material from within such features, the etch rate of the material within features having smaller CD differs from the etch rate of the material within features having larger CD and blanket areas of the substrate. This CD-dependent etching results in an uneven etch rate, and an uneven removal of material, across the substrate.

Therefore, new etch processes and methods of etching are needed to provide uniform etching of material within features of different CD, regardless of CD.

### SUMMARY

The present disclosure provides various embodiments of etch processes and methods to provide uniform etching of material within a plurality of features (such as, e.g., trenches, holes, slits, etc.) formed on a substrate, where one or more of the features have different critical dimension (CD). In the present disclosure, a cyclic process is used to provide uniform etching of the material within the features, regardless of CD. The cyclic process generally includes: (a) a surface modification step to chemically modify an exposed surface of the material and form a modified surface layer on the material, and (b) a removal step to selectively remove the modified surface layer without etching an underlying unmodified surface of the material. By using a cyclic process, the embodiments disclosed herein provide “CD-independent etching” of material formed within features of different CD and enable an even thickness of the material to be removed from the features across the substrate.

According to one embodiment, a method of etching is provided that utilizes the techniques described herein to provide CD-independent etching. The method may generally begin by providing a substrate having a target material and a wall material formed adjacent to the target material on at least two sides of the target material. The target material and the wall material may comprise two different materials. The target material and the wall material may also form a plurality of features, wherein a critical dimension (CD) of the plurality of features is different for one or more of the features. For example, the plurality of features may generally comprise at least a first feature having a smaller CD and a second feature having a larger CD.

The method may further include selectively etching the target material within the plurality of features. For example, the target material may be selectively etched by exposing the substrate to a plurality of different reactants in series to: (a) chemically modify an exposed surface of the target material by exposing the exposed surface of the target material to a gas-phase or liquid-phase reactant to form a modified surface layer having a self-limiting thickness, and (b) selectively remove the modified surface layer by exposing the modified surface layer to a chemical solution comprising a reactant, which differs from the gas-phase or liquid-phase reactant.

In the method described above, the chemical modification of the exposed surface of the target material and the selective removal of the modified surface layer provides uniform etching of the target material within the plurality of features, regardless of CD, by selectively removing only the modified surface layer. The wall material formed adjacent to the target material and the unmodified surface of the target material underlying the modified surface layer are not etched in chemical modification step. Once the modified surface layer is selectively removed to etch the target material, the chemical modification of the exposed surface of the target material and the selective removal of the modified surface layer may be sequentially and alternatingly performed a plurality of times to selectively etch a desired amount of the target material.

According to another embodiment, another method of etching is provided that utilizes the techniques described herein to provide CD-independent etching. Like the previous method, the method may generally begin by providing a substrate having a target material and a wall material formed adjacent to the target material on at least two sides of the target material. The target material and the wall material may comprise two different materials. The target material and the wall material may also form a plurality of features, wherein a critical dimension (CD) of the plurality of features is different for one or more of the features. For example, the plurality of features may generally comprise at least a first feature having a smaller CD and a second feature having a larger CD.

The method may further include performing a cyclic process to selectively etch the target material without etching the wall material. The cyclic process may include multiple cycles, where each cycle includes: (a) a surface modification step that includes exposing the substrate to a gas-phase or liquid-phase reactant to chemically modify an exposed surface of the target material and form a modified surface layer on the target material, wherein the gas-phase or liquid-phase reactant does not etch the target material or the wall material; and (b) a removal step that includes exposing the substrate to a liquid-phase reactant to selectively remove the modified surface layer of the target material without etching the wall material or an unmodified surface of the target material underlying the modified surface layer, wherein the liquid-phase reactant used during the removal step is different from the gas-phase or liquid-phase reactant used during the surface modification step. In doing so, the cyclic process described herein may provide uniform etching of the target material within the plurality of features, regardless of CD.

In some embodiments of the methods disclosed herein, the features formed on the substrate may comprise a plurality of trenches or holes, which are formed within the wall material and filled with the target material. In such embodiments, the cyclic process described herein may be used to provide uniform vertical etching of the target material within the plurality of trenches or holes, regardless of CD.

In other embodiments of the methods disclosed herein, the features formed on the substrate may comprise a plurality of nano-slits, which are formed within the wall material and filled with the target material. In such embodiments, the cyclic process described herein may be used to provide uniform horizontal etching of the target material within the plurality of nano-slits, regardless of CD.

In the methods disclosed herein, the target material and the wall material may each comprise a wide variety of materials, as long as the target material and the wall material are formed of different materials. In some embodiments, the target material may comprise silicon, a metal, an oxide, a nitride or a mixture thereof, and the wall material may be a dielectric material.

A wide variety of reactants may be used in the chemical modification (step a) and the selective removal (step b) to selectively remove a uniform amount of target material from the plurality of features, regardless of CD. In some embodiments, the gas-phase or liquid-phase reactant used to chemically modify the exposed surface of the target material may an oxidizing agent. When an oxidizing agent is used in the chemical modification (step a), the oxidizing agent may oxidize the exposed surface of the target material to form an oxidized surface layer, which is selectively removed by the chemical solution used in the selective removal (step b). Depending on the oxidizing agent used and the oxidized surface layer formed, the chemical solution used to selectively remove the oxidized surface layer may include one or more of: an acid, a base, an aqueous solvent, an organic solvent and a ligand.

In some embodiments, the oxidizing agent may be a liquid-phase oxidizing agent, such as hydrogen peroxide (H₂O₂), nitric acid (HNO₃), sulfuric acid (H₂SO₄), ammonium persulfate (APS), ferric chloride (FeCl₃), ozone (O₃) dissolved in water or oxygen (O₂) dissolved in water. In some embodiments, an oxidizing agent (such as H₂O₂) may be included within a chemical mixture, such as a sulfuric peroxide mixture (SPM), a standard clean 1 (SC1) mixture, or a standard clean 2 (SC2) mixture. In other embodiments, the oxidizing agent may be a gas-phase oxidizing agent, such as ozone (O₃), oxygen (O₂), nitrogen dioxide (NO₂) or nitrous oxide (N₂O).

In one example embodiment, the target material to be etched may be amorphous silicon (a-Si) and the wall material may be silicon carbon nitride (SiCN). In such an embodiment, the substrate may be exposed to hydrogen peroxide (H₂O₂) in the chemical modification (step a) to oxidize an exposed surface of the a-Si target material and form a silicon dioxide (SiO₂) surface layer on the a-Si. Next, the substate may be exposed to a chemical solution comprising hydrofluoric acid (HF) to etch the SiO₂ surface layer selective to a-Si and SiCN.

In another example embodiment, the target material to be etched may be titanium nitride (TiN) and the wall material may be hafnium dioxide (HfO₂). In such an embodiment, the substrate may be exposed to ozone (O₃) gas to oxidize an exposed surface of the TiN target material and form a titanium dioxide (TiO₂) surface layer on the TiN. Next, the substate may be exposed to a chemical solution comprising hydrochloric acid (HCl) to etch the TiO₂ surface layer selective to TiN and HfO₂.

In other embodiments, the gas-phase or liquid-phase reactant used to chemically modify the exposed surface of the target material may be a halogenating agent. For example, the halogenating agent may be a chlorinating agent, a brominating agent or a fluorinating agent. When a halogenating agent is used in the chemical modification (step a), the halogenating agent may halogenate the exposed surface of the target material to form a halogenated surface layer, which is selectively removed by the chemical solution used in the selective removal (step b). Depending on the halogenating agent used and the halogenated surface layer formed, the chemical solution used to selectively remove the halogenated surface layer may include one or more of: an acid, a base, an aqueous solvent, an organic solvent and a ligand.

As noted above and described further herein, the present disclosure provides various embodiments of methods that provide CD-independent etching of material. Of course, the order of discussion of the different steps as described herein has been presented for the sake of clarity. In general, these steps can be performed in any suitable order. Additionally, although each of the different features, techniques, configurations, etc., herein may be discussed in different places of this disclosure, it is intended that each of the concepts can be executed independently of each other or in combination with each other. Accordingly, the present invention can be embodied and viewed in many different ways.

Note that this Summary section does not specify every embodiment and/or incrementally novel aspect of the present disclosure or claimed inventions. Instead, the summary only provides a preliminary discussion of different embodiments and corresponding points of novelty over conventional techniques. For additional details and/or possible perspectives of the invention and embodiments, the reader is directed to the Detailed Description section and corresponding figures of the present disclosure as further discussed below.

### BRIEF DESCRIPTION OF THE DRAWINGS

A more complete understanding of the present inventions and advantages thereof may be acquired by referring to the following description taken in conjunction with the accompanying drawings, in which like reference numbers indicate like features. It is to be noted, however, that the accompanying drawings illustrate only exemplary embodiments of the disclosed concepts and are therefore not to be considered limiting of the scope, for the disclosed concepts may admit to other equally effective embodiments.

FIG. 1A is a cross-sectional view through a substrate having features of different critical dimension (CD) illustrating CD-dependent etching of material within the features when the substrate is exposed to a non-aqueous organic-based etch solution.

FIG. 1B is a cross-sectional view through a substrate having features of different critical dimension (CD) illustrating CD-dependent etching of material within the features when the substrate is exposed to an aqueous-based etch solution.

FIG. 2 is a graph illustrating the normalized etch rate vs. feature CD when a substrate is exposed to a non-aqueous organic-based etch solution and an aqueous-based etch solution as shown in FIGS. 1A and 1B.

FIG. 3 is a flowchart diagram illustrating one embodiment of a method of etching that utilizes the techniques described herein to provide CD-independent etching.

FIGS. 4A-4D illustrate one embodiment of a cyclic process that utilizes the techniques described herein to provide uniform vertical etching of material within features having different CD.

FIGS. 5A-5D illustrate another embodiment of a cyclic process that utilizes the techniques described herein to provide uniform horizontal etching of material within features having different CD.

FIG. 6 is a graph illustrating the normalized etch amount vs nano-slit CD (expressed in nm) when a cyclic process, as shown in FIGS. 5A-5D, is used to etch amorphous silicon (a-Si) nano-slits of varying CD (e.g., 10, 20 and 40 nm) adjacent to a silicon carbon nitride (SiCN) wall material.

FIG. 7 is a graph illustrating the normalized etch amount vs nano-slit CD (expressed in nm) when a cyclic process, as shown in FIGS. 5A-5D, is used to etch titanium nitride (TiN) nano-slits of varying CD (e.g., 4, 6 and 20 nm) adjacent to a hafnium dioxide (HfO₂) wall material.

FIG. 8 is a flowchart diagram illustrating another embodiment of a method of etching that utilizes the techniques described herein to provide CD-independent etching.

### DETAILED DESCRIPTION

The present disclosure provides various embodiments of processes and methods to provide uniform etching of material within a plurality of features (such as, e.g., trenches, holes, slits, etc.) formed on a substrate, where one or more of the features have different critical dimension (CD).

As noted in the Background Section, problems arise when conventional wet etch processes are used to remove material formed within narrow features (such as, e.g., trenches, holes, slits, etc.) having different CD. When an etch solution is used to remove material formed within features of different CD in a wet etch process, the rate at which the material is removed from the features (i.e., the etch rate) may differ depending on a variety of factors, such as the CD of the features, the etchant chemical(s) used within the etch solution, the solvent used within the etch solution, the ratio of etchant chemical(s) to solvent used within the etch solution, the pH of the etch solution and the wall material adjacent to the material being etched. Depending on such factors, the etch rate of the material removed from features having smaller CD may be faster (or slower) than the etch rate of the material removed from features having larger CD and blanket areas of the substrate. The difference in etch rate across features of different CD is known in the art as “CD-dependent etching.”

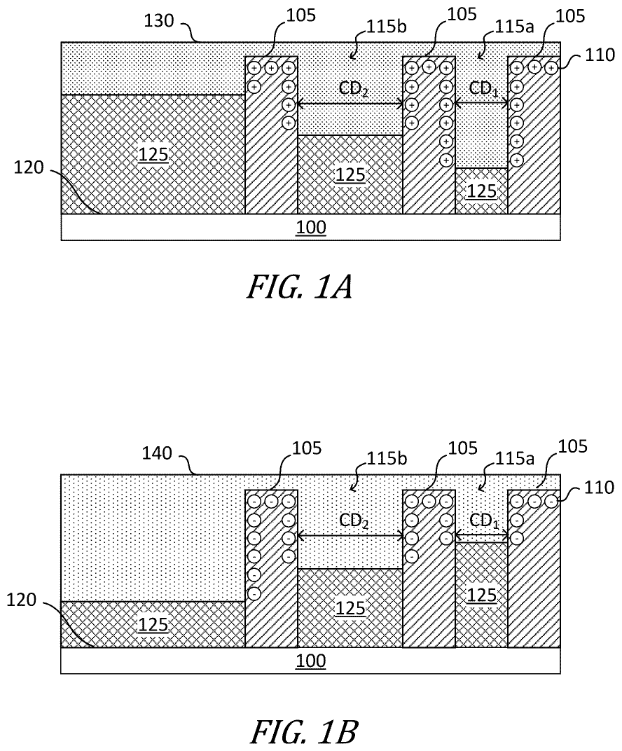

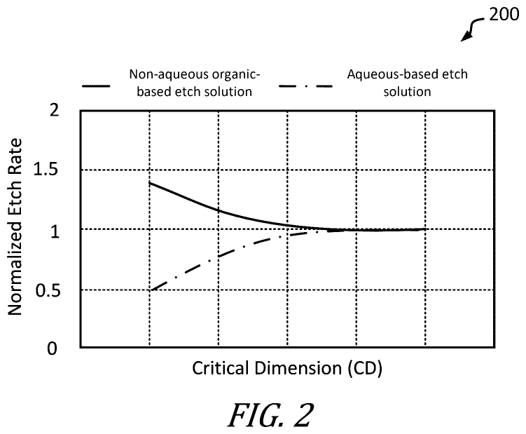

FIGS. 1A-1B and 2 illustrate CD-dependent etching of material deposited within features having different CD, and across more planar areas of a substrate, when the substrate is exposed to a non-aqueous organic-based etch solution 130 (FIGS. 1A and 2) and an aqueous-based etch solution 140 (FIGS. 1B and 2). An aqueous-based etch solution 140 is a solution that includes one or more etchant chemicals mixed with an aqueous solvent (e.g., water (H₂O) or deionized water). A non-aqueous organic-based etch solution 130, on the other hand, is a solution that includes one or more etchant chemicals mixed with an organic solvent (e.g., an alcohol, a polyhydric alcohol, acetic acid, a ketone or another organic solvent).

The substrate 100 shown in FIGS. 1A-1B is provided with a plurality of structures 105 (e.g., metal lines, fins, etc.) that extend above a surface of the substrate 100. Each of the plurality of structures 105 is separated by a feature 115 (such as, e.g., a gap, trench, hole, etc.). A critical dimension (CD) of the features 115 may be the same, or may be different, as shown in FIGS. 1A-1B. In the embodiments shown in FIGS. 1A-1B, the substrate 100 is depicted as having a first feature 115a having a smaller CD (CD₁) and a second feature 115b having a larger CD (CD₂). The CD of the plurality of features 115 is relatively small (e.g., less than 100 nm) compared to the more planar areas 120 of the substrate 100 surrounding the plurality of structures 105.

A material 125 to be etched is deposited onto a surface of the substrate 100, the plurality of structures 105 and within the features 115 formed between the plurality of structures 105. The material 125 may include a wide variety of semiconductor materials. For example, the material 125 may be an oxide, a dielectric material, silicon or a metal. In one example, the material 125 may be a silicon oxide (such as, e.g., silicon dioxide, SiO₂). Other oxide and dielectric materials, including low-k dielectric materials, may also be formed within the plurality of features 115 and etched.

When etching the material 125 formed within the plurality of features 115, the etch rate of the material 125 may depend on a variety of factors, including the critical dimension (CD) of the features 115, the particular etchant chemical(s) and/or reactive species used within the etch solution, the particular solvent used within the etch solution, the ratio of etchant chemical(s) to solvent used within the etch solution and/or the pH of the etch solution. In addition to these factors, the electric potential of the wall material 110 adjacent to the material 125 being etched may also affect the etch rate of the material 125, depending on the etch solution used.

A wide variety of etchant chemicals can be used within the non-aqueous organic-based etch solution 130 (shown in FIGS. 1A and 2) and the aqueous-based etch solution 140 (shown in FIGS. 1B and 2). In some cases, the etchant chemicals included within the etch solutions 130 and 140 may contain an anion (negatively charged ion) as the main reactive species. Examples of such etchant chemicals include, but are not limited to, hydrofluoric acid (HF), ammonium hydroxide (NH₄OH), hydrochloric acid (HCl), hydrogen peroxide (H₂O₂), nitric acid (HNO₃), phosphoric acid (H₃PO₄), potassium hydroxide (KOH) and Tetramethylammonium hydroxide (TMAH). In other cases, the etchant chemicals included within the etch solutions 130 and 140 may contain a cation (positively charged ion) as the main reactive species.

In the wet etch process shown in FIG. 1A, the substrate 100 is exposed to non-aqueous organic-based etch solution 130 that includes one or more etchant chemicals containing anions as the main reactive species and an organic solvent (such as, e.g., isopropyl alcohol (IPA), ethylene glycol (EG), acetic acid (AA), or propylene carbonate (PC)). When the substrate 100 is exposed to such a non-aqueous organic-based etch solution 130, portions of the features 115 exposed to the non-aqueous organic-based etch solution 130 may exhibit a positive surface potential, as shown in FIG. 1A, depending on the pH of the etch solution and the wall material 110 used to form the features 115. The anions within the etchant chemical(s) are attracted to the positively charged surface of the wall material 110. This increases the local concentration of anions within the features 115, which increases the etch rate of the material 125 deposited within the features 115 compared to the more planar areas 120 of the substrate 100. Thus, the material 125 is etched faster within the plurality of features 115 and slower within the more planar areas 120 of the substrate 100 surrounding the plurality of structures 105. This is shown schematically in FIG. 1A and in the graph 200 shown in FIG. 2. When features 115 of different CD are formed within the plurality of structures 105, as shown in FIG. 1A, the increase in etch rate is more pronounced within features having smaller CD (such as feature 115a) and less pronounced within features having larger CD (such as feature 115b). However, the etch rate within the features 115 is significantly faster than the etch rate achieved across the more planar areas 120 of the substrate 100.

In the wet etch process shown in FIG. 1B, the substrate 100 is exposed to an aqueous-based etch solution 140 that includes one or more etchant chemicals containing anions as the main reactive species and an aqueous solvent (e.g., water (H₂O) or deionized water). When the substrate 100 is exposed to such an aqueous-based etch solution 140, portions of the features 115 exposed to the aqueous-based etch solution 140 may exhibit a negative surface potential, as shown in FIG. 1B, depending on the pH of the etch solution and the wall material 110 used to form the features 115. The negative surface potential of the wall material 110 repels the anions within the etchant chemical(s) to decrease its local concentration in the features 115, and thus, decrease the etch rate of the material 125 deposited within the features 115. When features 115 of different CD are formed within the plurality of structures 105, as shown in FIG. 1B, the decrease in etch rate is more pronounced in features having smaller CD (such as feature 115a) and less pronounced in features having larger CD (such as feature 115b). As a result, the material 125 is etched slower in features having smaller CD (such as feature 115a) and faster in features having larger CD (such as feature 115b). As shown in FIG. 1B, the etch rate across the more planar areas 120 of the substrate is significantly faster than the etch rate within the features 115.

As shown in FIGS. 1A-1B and 2, non-aqueous organic-based etch solutions 130 and aqueous-based etch solutions 140 may sometimes have the opposite effect on etch rate. When a non-aqueous organic-based etch solution 130 is used to etch the material 125, the etch rate is increased within features of smaller CD (such as feature 115a) and decreased within features of larger CD (such as feature 115b). However, the opposite is true when an aqueous-based etch solution 140 is used to etch the material 125. Thus, wet etch processes using non-aqueous organic-based etch solutions 130 or aqueous-based etch solutions 140 suffer from CD-dependent etching, which is undesirable as it results in an uneven etch rate, and an uneven removal of material across the substrate.

Commonly assigned U.S. Pat. No. 12,100,599, entitled “Wet Etch Process and Method to Provide Uniform Etching of Material Formed within Features Having Different Critical Dimension (CD),” discloses various wet etch processes and methods of etching that provide uniform etching of material within features of different CD, regardless of CD. The commonly assigned '599 Patent takes advantage of the difference in etch rate that often occurs when non-aqueous organic-based etch solutions and aqueous-based etch solutions are used to etch a material formed within features (e.g., trenches, holes, slits, etc.) having different CD.

In the '599 Patent, a non-aqueous organic-based etch solution 130 and an aqueous-based etch solution 140 is combined (either in series or in parallel) within a wet etch process to provide uniform etching of the material, regardless of CD. In the wet etch process disclosed in the '599 Patent, each etch solution supplied to the substrate surface removes some amount of the material 125 from the features 115. However, the etch rate at which the material 125 is removed from the features having smaller CD (such as feature 115a) and the features having larger CD (such as feature 115b) differs, depending on the etch solution (130 or 140) supplied, the material 125 being etched, the wall material 110 adjacent to the material 125 and other factors. By combining a non-aqueous organic-based etch solution 130 with an aqueous-based etch solution 140 in series, the wet etch processes and methods disclosed in the '599 Patent utilize the opposing effects of CD-dependent etching to ultimately remove a uniform amount of material 125 from the features 115, regardless of CD. In doing so, the wet etch processes and methods disclosed in the '599 Patent provide “CD-independent etching.”

The wet etch processes and methods disclosed in the '599 Patent provide CD-independent etching of various target etch materials and wall materials. For example, the previously disclosed wet etch processes and methods demonstrated a uniform etch rate and uniform etching of a silicon dioxide (SiO₂) material formed within trenches of varying CD when the SiO₂ material is adjacent to a wall material comprising a silicon-containing material (such as, e.g., amorphous silicon, (a-Si), polysilicon (poly-Si), silicon nitride (SiN), silicon carbon nitride (SiCN) or silicon oxynitride (SiON)). While suitable for etching some target materials and wall materials, the wet etch processes and methods disclosed in the '599 Patent do not provide CD-independent etching in other material combinations. Thus, new etch processes and methods are needed to provide CD-independent etching.

The present disclosure provides new etch processes and methods that provide uniform etching of material within narrow features (such as, e.g., gaps, trenches, holes, slits, etc.) having different CD. Unlike the wet etch processes and methods disclosed in the '599 Patent, which take advantage of the difference in etch rate that occurs when different etchant chemicals are supplied to a substrate surface in series, the processes and methods disclosed herein combine a surface modification step with a selective removal step in a cyclic process to provide CD-independent etching.

As described in more detail below, the cyclic process disclosed herein uses: (a) a surface modification step to chemically modify an exposed surface of a target material (i.e., a material to be etched) and form a modified surface layer on the target material, and (b) a removal step to selectively remove the modified surface layer without etching an underlying unmodified surface of the material. By using a cyclic surface modification and removal process, the new etch processes and methods disclosed herein provide CD-independent etching of a wide variety of target materials that may be formed within features of different CD and enable an even thickness of the target material to be removed from the features across the substrate.

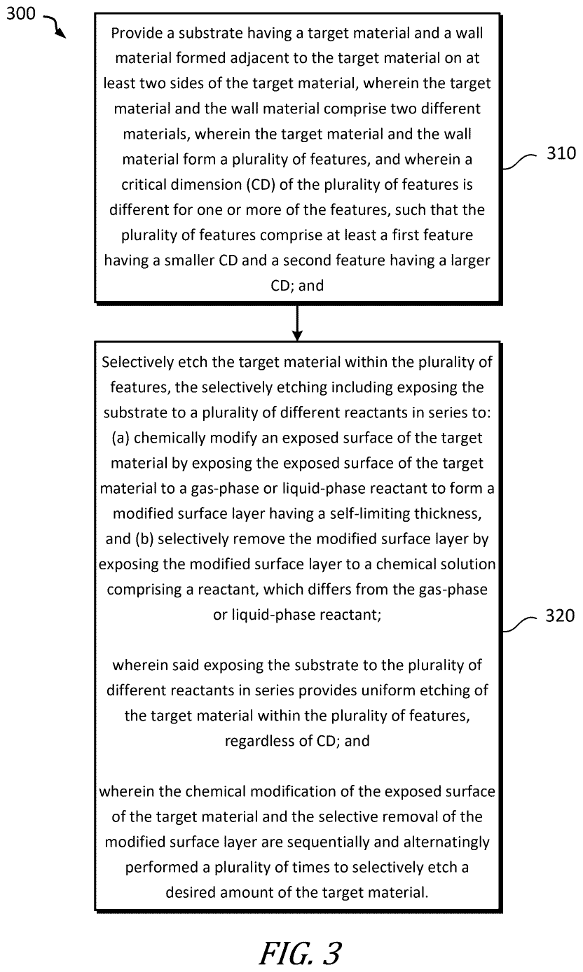

FIG. 3 illustrates a method 300 of etching that utilizes the techniques described herein to provide CD-independent etching of various target materials. It will be recognized that the method 300 shown in FIG. 3 is merely exemplary and additional methods may utilize the techniques disclosed herein. Further, additional processing steps may be added to the method 300 as the steps described are not intended to be exclusive. Moreover, the order of the steps is not limited to the order shown in the figures as different orders may occur and/or various steps may be performed in combination or at the same time.

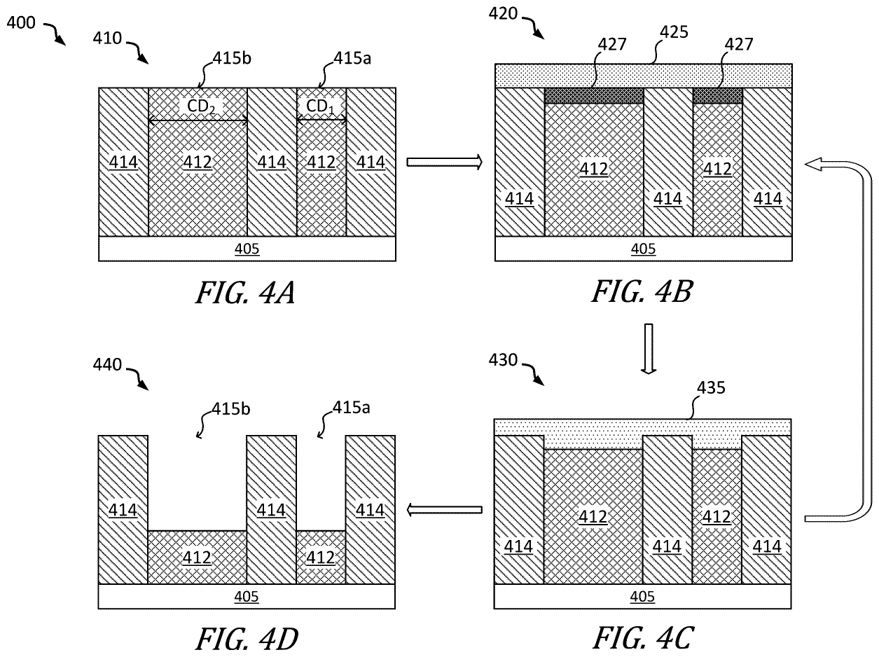

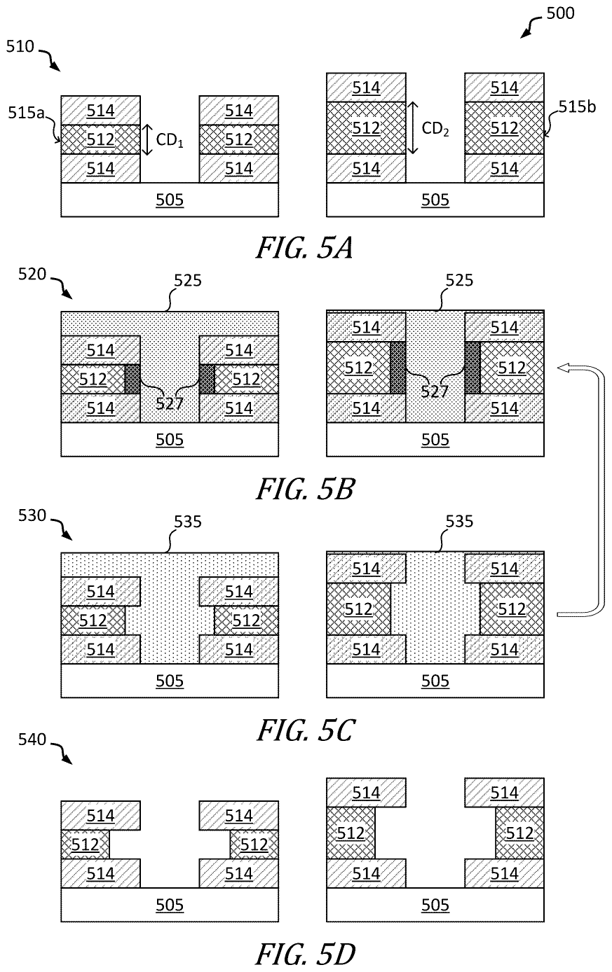

As shown in FIG. 3, the method 300 may begin by providing a substrate having a target material and a wall material formed adjacent to the target material on at least two sides of the target material (in step 310). The target material and the wall material are two different materials. As depicted in the example embodiments shown in FIGS. 4A-4D and FIGS. 5A-5D, the target material and the wall material may form a plurality of features such as, for example, gaps, trenches, holes, slits, etc. A critical dimension (CD) of the plurality of features is different for one or more of the features. For example, in the embodiments disclosed herein, the plurality of features may include at least a first feature having a smaller CD and a second feature having a larger CD.

The method 300 further includes selectively etching the target material within the plurality of features (in step 320). In general, the target material may be selectively etched in step 320 by exposing the substrate to a plurality of different reactants in series to: (a) chemically modify an exposed surface of the target material by exposing the exposed surface of the target material to a gas-phase or liquid-phase reactant to form a modified surface layer having a self-limiting thickness, and (b) selectively remove the modified surface layer by exposing the modified surface layer to a chemical solution comprising a reactant, which differs from the gas-phase or liquid-phase reactant.

In the method 300 shown in FIG. 3, the chemical modification of the exposed surface of the target material and the selective removal of the modified surface layer provides uniform etching of the target material within the plurality of features, regardless of CD, by removing only the modified surface layer from the target material to selectively etch the target material. The wall material formed adjacent to the target material and the unmodified surface of the target material underlying the modified surface layer are not etched in step 320. Once the modified surface layer is selectively removed to etch the target material, the chemical modification of the exposed surface of the target material and the selective removal of the modified surface layer may be sequentially and alternatingly performed a plurality of times to selectively etch a desired amount of the target material.

FIGS. 4A-4D illustrate one embodiment of a cyclic process 400 that utilizes the techniques described herein to provide uniform etching of material within features having different CD. In the embodiment shown in FIGS. 4A-4D, the cyclic process 400 is performed on a substrate having gaps, trenches or holes, which have different CD. The CD of the gaps, trenches or holes shown in FIGS. 4A-4D may be relatively small compared to more planar areas of the substrate. In some embodiments, the CD of the trenches or holes may be, for example, less than 100 nm.

The cyclic process 400 may begin (in step 410) by providing a substrate 405 having a target material 412 and a wall material 414 formed adjacent to the target material 412 on at least two sides of the target material 412, as shown in FIG. 4A. The substrate 405 further comprises a plurality of features 415, such as narrow gaps, trenches or holes, which are formed within the wall material 414 and filled with the target material 412. In the example shown in FIG. 4A, the substrate 405 is provided with a first feature 415a having a smaller CD (CD₁) and a second feature 415b having a larger CD (CD₂). As noted above, the CD of the features 415 may be relatively small (e.g., less than 100 nm) compared to more planar areas of the substrate 405.

The target material 412 and the wall material 414 may each comprise a wide variety of materials, as long as the target material 412 and the wall material 414 are formed of different materials. In some embodiments, the target material 412 may comprise silicon, a metal, an oxide, a nitride or a mixture thereof, and the wall material 414 may be a dielectric material. In one example, the target material 412 may be a first silicon-containing material and the wall material 414 may be a second silicon-containing material, which differs from the first silicon-containing material. Examples of silicon-containing materials include, but are not limited to, amorphous silicon (a-Si), polysilicon (poly-Si), silicon nitride (SiN), silicon carbon nitride (SiCN) and silicon oxynitride (SiON). In one example embodiment, the target material 412 may be amorphous silicon (a-Si) and the wall material 414 may be silicon carbon nitride (SiCN).

In another example, the target material 412 may be a transition metal and the wall material 414 may be a dielectric material. Examples of transition metals include titanium (Ti), vanadium (V), chromium (Cr), cobalt (Co), nickel (Ni), copper (Cu), zinc (Zn), zirconium (Zr), niobium (Nb), molybdenum (Mo), ruthenium (Ru), silver (Ag), cadmium (Cd), hafnium (Hf), tantalum (Ta), tungsten (W), osmium (Os), iridium (Ir), platinum (Pt), gold (Au), etc. Examples of dielectric materials include, but are not limited to, silicon dioxide (SiO₂), silicon nitride (Si₃N₄), aluminum oxide (Al₂O₃), hafnium dioxide (HfO₂), tantalum oxide (Ta₂O₅), zirconium dioxide (ZrO₂), and titanium dioxide (TiO₂).

In yet another example, the target material 412 may be a transition metal oxide and the wall material 414 may be a dielectric material or a transition metal dichalcogenide (TMD) material. Examples of transition metal oxides include, but are not limited to, titanium dioxide (TiO₂), tantalum oxide (Ta₂O₅), zirconium dioxide (ZrO₂), hafnium dioxide (HfO₂), hafnium zirconium oxide (HfₓZr₍₁₋ₓ₎O₂). Examples of TMD materials include, but are not limited to, molybdenum disulfide (MoS₂), molybdenum diselenide (MoSe₂), tungsten disulfide (WS₂) and tungsten diselenide (WSe₂).

In a further example, the target material 412 may be a transition metal nitride and the wall material 414 may be a transition metal oxide or another dielectric material. Examples of transition metal nitrides include, but are not limited to, titanium nitride (TiN), zirconium nitride (ZrN), hafnium nitride (HfN), vanadium nitride (VN), chromium nitride (CrN), molybdenum nitride (MoN), and tungsten nitride (WN). In one example embodiment, the target material 412 may be titanium nitride (TiN) and the wall material 414 may be hafnium dioxide (HfO₂).

In the cyclic process 400, the target material 412 is selectively etched or removed from the features 415 of different CD by: (a) exposing the exposed surface of the target material 412 to a gas-phase or liquid-phase reactant 425 (in step 420) to chemically modify an exposed surface of the target material 412 and form a modified surface layer 427 having a self-limiting thickness on the target material 412, as shown in FIG. 4B, and (b) exposing the modified surface layer 427 to a chemical solution 435 comprising a liquid-phase reactant, which differs from the gas-phase or liquid-phase reactant (in step 430), to selectively remove the modified surface layer, as shown in FIG. 4C. The chemical modification step (step 420) and the selective removal step (step 430) are repeatedly performed, in a cyclical manner, until a desired amount of the target material 412 is selectively etched or removed from the features 415 (in step 440), as shown in FIG. 4D.

Unlike conventional wet etch processes, which use one or more etchant chemicals to remove different amounts of material from features of different CD at different etch rates, the cyclic process shown in FIGS. 3 and 4A-4D utilizes self-limited surface modification and selective removal of the modified surface layer 427 to remove essentially the same amount of target material 412 (i.e., the self-limited thickness) from the features 415a and 415b each etch cycle independent of CD. The amount of target material 412 removed from the features 415a and 415b each etch cycle may range from one or more monolayers to tens of nanometers (or more), depending on the target material 412 being etched, the gas-phase or liquid-phase reactant 425 used in chemical modification step (step 420) and the liquid-phase reactant used in the selective removal step (step 430).

A wide variety of reactants may be used in the chemical modification step (step 420) and the selective removal step (step 430) to selectively remove the same amount of target material 412 from the features 415, regardless of CD. The choice of reactants depends on several factors, such as the target material 412 being etched, the wall material 414 adjacent to the target material 412 and the modified surface layer 427 formed in step 420. In general, the gas-phase or liquid-phase reactant 425 used in step 420 should chemically modify the exposed surface of the target material 412 without etching the target material 412 or the wall material 414 adjacent thereto. In addition, the chemical solution 435 used in step 430 should selectively remove the modified surface layer 427 without etching the wall material 414 or an unmodified surface of the target material 412 underlying the modified surface layer 427. In doing so, the cyclic process 400 shown in FIGS. 4A-4D enables a uniform amount of the target material 412 to be removed from the plurality of features 415 independent of CD.

In some embodiments, the gas-phase or liquid-phase reactant 425 may be an oxidizing agent. When an oxidizing agent is used in step 420, the oxidizing agent oxidizes the exposed surface of the target material 412 to form an oxidized surface layer, which is selectively removed by the chemical solution 435 used in step 430. Depending on the oxidizing agent used and the oxidized surface layer formed, the chemical solution 435 used to selectively remove the oxidized surface layer in step 430 may include one or more of: an acid, a base, an aqueous solvent, an organic solvent and a ligand.

In some embodiments, the oxidizing agent used in step 420 may oxidize the exposed surface of the target material 412 via a self-limiting reaction to form an oxidized surface layer having a self-limited thickness. As known in the art, a “self-limiting reaction” is a chemical reaction that inherently ceases once a specific condition is met such as, for example, when a reactant is used up, the reactive sites on a surface are entirely depleted or an inert passivation layer is formed on the surface that prevents further reaction. In other embodiments, the thickness of the oxidized surface layer may not be limited to a self-limited thickness. For example, parameters such as oxidizing agent concentration, temperature, process time, and even the type of oxidizing agent can be selected to tune the oxidized layer thickness. In such embodiments, the cyclic process 400 shown in FIGS. 4A-4D may provide higher etch amounts per cycle than wet ALE.

A wide variety of oxidizing agents can be used in step 420 to form an oxidized surface layer on the target material 412. In some embodiments, a liquid-phase oxidizing agent such as hydrogen peroxide (H₂O₂), nitric acid (HNO₃), ozone (O₃) dissolved in water, or oxygen (O₂) dissolved in water can be used to oxidize the exposed surface of the target material 412 and form an oxidized surface layer on the target material 412. In some embodiments, a liquid-phase oxidizing agent (such as H₂O₂) may be included within a chemical mixture, such as a sulfuric peroxide mixture (SPM, H₂SO₄:H₂O₂:H₂O), a standard clean 1 (SC1, NH₄OH:H₂O2:H₂O) mixture or a standard clean 2 (SC2, HCl:H₂O₂:H₂O) mixture.

Other peroxide and non-peroxide oxidizers can also be used to oxidize the exposed surface of the target material 412 and form an oxidized surface layer in step 420. Examples of non-peroxide oxidizers include, but are not limited to, sulfuric acid (H₂SO₄), ammonium persulfate (APS), ferric chloride (FeCl₃), osmium tetroxides, ruthenium tetroxides, ruthenates, manganates, permanganates, periodates, and metal nitrates. Examples of peroxide oxidizers include hydrogen peroxide (H₂O₂), organic peroxides (such as di-tert-butyl peroxide (C₈H₁₈O₂) and tert-butyl peroxybenzoate (C₁₁H₁₄O₃)), monoperoxides (such as tert-butyl hydroperoxide (C₄H₁₀O₂)), peroxy acids (such as peracetic acid (C₂H₄O₃)).

It is recognized, however, that the oxidation step is not strictly limited to the liquid phase. In other embodiments, a gas-phase oxidizing agent, such as ozone (O₃), oxygen (O₂), nitrogen dioxide (NO₂) or nitrous oxide (N₂O), may be used to oxidize the exposed surface of the target material 412 and form the oxidized surface layer. Other gas-phase oxidants may also be used.

In some embodiments, the gas-phase or liquid-phase reactant 425 may be a halogenating agent. When a halogenating agent is used in step 420, the halogenating agent halogenates the exposed surface of the target material 412 to form a halogenated surface layer, which is selectively removed by the liquid-phase reactant used in step 430. Depending on the halogenating agent used and the halogenated surface layer formed, the chemical solution 435 used to selectively remove the halogenated surface layer in step 430 may include one or more of: an acid, a base, an aqueous solvent, an organic solvent and a ligand.

A wide variety of halogenating agents, including chlorinating agents, brominating agents and fluorinating agents, can be used in step 420 to form a halogenated surface layer. Examples of liquid-phase chlorinating agents include, but are not limited to, trichloroisocyanuric acid (TCCA), oxalyl chloride, N-chlorosuccinimide, 1-chlorobenzotriazole, Chloramine-T and tert-butyl-N-chlorocyanamide. Examples of liquid-phase fluorinating agents include, but are not limited to, 1-chloromethyl-4-fluoro-1,4-diazoniabicyclo[2.2.2]octane bis(tetrafluoroborate), 1-fluoropyridinium triflate, 1-fluoro-2,4,6-trimethylpyridinium tetrafluoroborate, N-fluorobenzenesulfonimide, fluoroxytrifluoromethane, perchloryl fluoride, xenon difluoride and N-fluorobis[(trifluoromethyl)sulfonyl]imide. Examples of liquid-phase brominating agents include, but are not limited to, N-bromosuccinimide, dibromoisocyanuric acid, tribromocyanuric acid, 1,3-Dibromo-5,5-Dimethylhydantoin and N-Bromoacetamide. In some embodiments, a halogen gas or gas mixture containing chlorine, fluorine, bromine or iodine may be used to halogenate the exposed surface of the target material 412 to form a halogenated surface layer.

The modified surface layer 427 formed in step 420 may be selectively removed in step 430 using a wide variety of chemical solutions 435 and liquid-phase reactants. As noted above, the chemical solution 435 may generally include one or more of: an acid, a base, an aqueous solvent, an organic solvent and a ligand. A wide variety of acids, bases, organic solvents and/or ligands can be used to selectively remove the modified surface layer 427 without etching the wall material 414 or an unmodified surface of the target material 412 underlying the modified surface layer 427.

Examples of acids that may be used to remove the modified surface layer 427 include, but are not limited to, hydrofluoric acid (HF), hydrochloric acid (HCl), citric acid (C₆H₈O₇), acetic acid (CH₃COOH), phosphoric acid (H₃PO₄) and other non-oxidizing acids that etch the modified surface layer 427 selective to the unmodified target material 412 and the adjacent wall material 414. Examples of bases that may be used to remove the modified surface layer 427 include, but are not limited to, ammonium hydroxide (NH₄OH), sodium hydroxide (NaOH), tetramethylammonium hydroxide (TMAH), potassium hydroxide (KOH), calcium hydroxide (Ca(OH)₂), potassium carbonate (K₂CO₃), ammonium carbonate ((NH₄)₂CO₃) and other non-oxidizing bases that etch the modified surface layer 427 selective to the unmodified target material 412 and the adjacent wall material 414.

In some embodiments, the chemical solution 435 may additionally or alternatively include an aqueous solvent (e.g., water or deionized water), an organic solvent and/or a ligand. Examples of organic solvents include, but are not limited to, methanol (CH₃OH), diethyl ether ((C₂H₅)₂O), ethyl acetate (C₄H₈O₂), acetonitrile (C₂H₃N), dimethyl sulfoxide (C₂H₆OS), isopropyl alcohol (IPA), another alcohol, a ketone or an acetate. Examples of ligands include, but are not limited to, carboxylic acids (such as, e.g., oxalic acid, formic acid, acetic acid, etc.), amine-containing ligands (such as, e.g., cupferron, ethylenediamine, ethylenediaminetetraacetic acid (EDTA), iminodiacetic acid, etc.), ascorbate anion-containing ligands (such as, e.g., ascorbic acid, sodium ascorbate, calcium ascorbate or potassium ascorbate, etc.) and other molecules that bind to metal surfaces.

In one example embodiment, the target material 412 to be etched may be amorphous silicon (a-Si) and the wall material 414 may be silicon carbon nitride (SiCN). In such an embodiment, a silicon (Si) substrate 405 comprising a plurality of features 415 of different CD can be exposed to a first chemical solution comprising hydrogen peroxide (H₂O₂) in step 420 to oxidize an exposed surface of the a-Si target material and form a silicon dioxide (SiO₂) surface layer on the a-Si. In one example, the SiO₂ surface layer can be etched selective to Si, a-Si and SiCN in step 430 using a second chemical solution comprising hydrofluoric acid (HF).

In another example embodiment, the target material 412 to be etched may be titanium nitride (TiN) and the wall material 414 may be hafnium dioxide (HfO₂). In such an embodiment, a silicon (Si) substrate 405 comprising a plurality of features 415 of different CD can be exposed to ozone (O₃) gas or O₃ water to oxidize an exposed surface of the TiN target material and form a titanium dioxide (TiO₂) surface layer on the TiN. In one example, the TiO₂ surface layer can be etched selective to Si, TiN and HfO₂ in step 430 using a chemical solution comprising hydrochloric acid (HCl).

In this example, O₃ gas or O₃ water is used to oxidize the TiN surface instead of H₂O₂, since H₂O₂ tends to etch TiN. While O₃ is provided as a possible oxidizer for TiN, other liquid and gas-phase oxidants that oxidize TiN without etching TiN or the surrounding wall material may also be used. Similarly, HCl is used in this example to etch TiO₂ instead of HF, since HF etches TiN. Thus, HCl provides better etch selectivity than HF when removing TiO₂. Although HCl is provided as a possible etchant for TiO₂, other liquid-phase reactants may also be used to remove TiO₂ selective to Si, TiN and HfO₂.

In other embodiments, a first chemical solution comprising a halogenating agent (e.g., a chlorinating agent, such as TCCA) dissolved in an organic solvent (such as, e.g., ethyl acetate) can be used to halogenate the TiN surface and form a titanium halide or oxyhalide surface layer, which can be selectively removed via a second chemical solution comprising an acid (or an acid and a ligand), as disclosed in commonly assigned U.S. patent application Ser. No. 19/042,196, entitled “Methods for Wet Atomic Layer Etching of Titanium Nitride Using Halogenation.”

Other combinations of chemical solutions can also be used to chemically modify and selectively remove various transition metals, transition metal oxides and silicon oxides as disclosed, for example, in commonly assigned to U.S. Pat. No. 10,982,335, entitled “Wet Atomic Layer Etching Using Self-Limiting and Solubility-limited Reactions;” U.S. Pat. No. 11,802,342, entitled “Methods for Wet Atomic Layer Etching of Ruthenium;” U.S. Pat. No. 11,866,831, entitled “Methods for Wet Atomic Layer Etching of Copper;” U.S. Patent Application Publication No. 2022/0148882, entitled “Methods for Etching a Substrate Using a Hybrid Wet Atomic Layer Etching Process;” U.S. Patent Application Publication No. 2023/0121246, entitled “Methods for Wet Atomic Layer Etching of Noble Metals;” U.S. patent application Ser. No. 18/240,142, entitled “Methods for Wet Atomic Layer Etching of Molybdenum;” U.S. patent application Ser. No. 18/542,181, entitled “Methods for Wet Atomic Layer Etching of Transition Metal Oxide Dielectric Materials;” U.S. patent application Ser. No. 18/602,858, entitled “Methods for Wet Atomic Layer Etching of Silicon Dioxide;” U.S. patent application Ser. No. 18/619,491, entitled “Methods for Wet Atomic Layer Etching of Tungsten;” U.S. patent application Ser. No. 18/636,818, entitled “Methods for Wet Atomic Layer Etching of Molybdenum in Aqueous Solution;” and U.S. patent application Ser. No. 18/900,795, entitled “Methods for Wet Atomic Layer Etching of Tungsten Using Halogenation;” the entirety of which are incorporated by reference.

For example, various oxidizers (such as O₂, O₃, H₂O, N₂O or H₂O₂) can be used to oxidize a cobalt (Co) surface and form a cobalt oxide surface layer, which can be selectively removed via exposure to a complexing agent (e.g., a carboxylate acid, such as citric acid, acetic acid, etc.) and an aqueous solution, as disclosed in commonly assigned U.S. Pat. No. 10,982,335, entitled “Wet Atomic Layer Etching Using Self-Limiting and Solubility-limited Reactions.” Various oxidizers can also be used to oxidize a copper (Cu) surface and form a copper oxide surface layer. Once formed, the copper oxide surface layer can be selectively removed via exposure to a complexing agent (e.g., a carboxylate acid, such as acetic acid, oxalic acid, mandelic acid, malic acid, maleic acid or fumaric acid) and an aqueous solution comprising a base, as disclosed in commonly assigned U.S. Pat. No. 11,866,831, entitled “Methods for Wet Atomic Layer Etching of Copper.” Other oxidizing agents and halogenating agents can be used to oxidize and/or halogenate other transition metals and transition metal oxides to form transition metal halides or oxyhalides, which can be selectively removed in various chemical solutions, as disclosed in the various commonly assigned patents, publications and applications mentioned above.

FIGS. 4A-4D illustrates how a cyclic process 400 as described above can be used to provide uniform vertical etching of a target material 412 within a plurality of gaps, trenches or holes, regardless of CD. While the horizontal CD of these features may be relatively small (e.g., less than 100 nm), the vertical depth and/or aspect ratio of the features may be significantly larger (e.g., 10:1, 20:1, 40:1, 50:1, 100:1, etc.). Thus, in some embodiments, the cyclic process 400 described herein may be used to provide uniform vertical etching in high aspect ratio features having different CD. It is recognized that the techniques described herein are not strictly limited to vertical etching of material formed within gaps, trenches or holes, and may be alternatively performed on a substrate having other features of varying CD. For example, the techniques described herein may be used to provide uniform horizontal etching of material formed within nano-slits of various thickness, as shown for example in FIGS. 5A-5D.

FIGS. 5A-5D illustrate one embodiment of a cyclic process 500 that utilizes the techniques described herein to provide uniform horizontal etching of material within features having different CD. In the embodiment shown in FIGS. 5A-5D, the cyclic process 500 is performed on a substrate 505 having nano-slits 515 of various thickness. In some embodiments, a thickness, or critical dimension (CD), of the nano-slits 515 may be, for example, less than 100 nm.

Like the previous process shown in FIGS. 4A-4B, the cyclic process 500 shown in FIGS. 5A-5D may begin (in step 510) by providing a substrate 505 having a target material 512 to be etched and a wall material 514 formed adjacent to the target material 512 on at least two sides of the target material 512. In the example embodiment shown in FIG. 5A, the target material 512 to be etched is a nano-slit 515, which is sandwiched between and formed adjacent to the wall material 514. As shown further in FIG. 5A, the nano-slits 515 formed on the substrate 505 may have different thickness, or CD. For example, the substrate 505 may be provided with at least a first nano-slit 515a having a smaller CD (CD₁) and a second nano-slit 515b having a larger CD (CD₂). As noted above, the CD of the nano-slits 515 may be relatively small (e.g., less than 100 nm) compared to more planar areas of the substrate 505.

In the cyclic process 500, the target material 512 is selectively etched or removed from the nano-slits 515 of different CD by: (a) exposing the exposed surface of the target material 512 to a gas-phase or liquid-phase reactant 525 (in step 520) to chemically modify an exposed surface of the target material 512 and form a modified surface layer 527 having a self-limiting thickness on the target material 512, as shown in FIG. 5B, and (b) exposing the modified surface layer 527 to a chemical solution 535 comprising a liquid-phase reactant, which differs from the gas-phase or liquid-phase reactant (in step 530), to selectively remove the modified surface layer, as shown in FIG. 5C. The chemical modification step (step 520) and the selective removal step (step 530) are repeatedly performed, in a cyclical manner, until a desired amount of the target material 512 is selectively etched or removed from the nano-slits 515 (in step 540), as shown in FIG. 5D.

Like the previous process shown in FIGS. 4A-4B, the cyclic process 500 shown in FIGS. 5A-5D may use a wide variety of reactants in the chemical modification step (step 520) and the selective removal step (step 530) to selectively remove the same amount of target material 512 from the nano-slits 515, regardless of CD. As noted above, the choice of reactants may generally depend on the target material 512 being etched, the wall material 514 adjacent to the target material 512 and the modified surface layer 527 formed in step 520. In general, the gas-phase or liquid-phase reactant 525 used in step 520 should chemically modify the exposed surface of the target material 512 without etching the target material 512 or the wall material 514 adjacent thereto. In addition, the chemical solution 535 used in step 530 should selectively remove the modified surface layer 527 without etching the wall material 514 or an unmodified surface of the target material 512. In doing so, the cyclic process 500 shown in FIGS. 5A-5D enables a uniform amount of the target material 512 to be removed from the nano-slits 515 independent of CD.

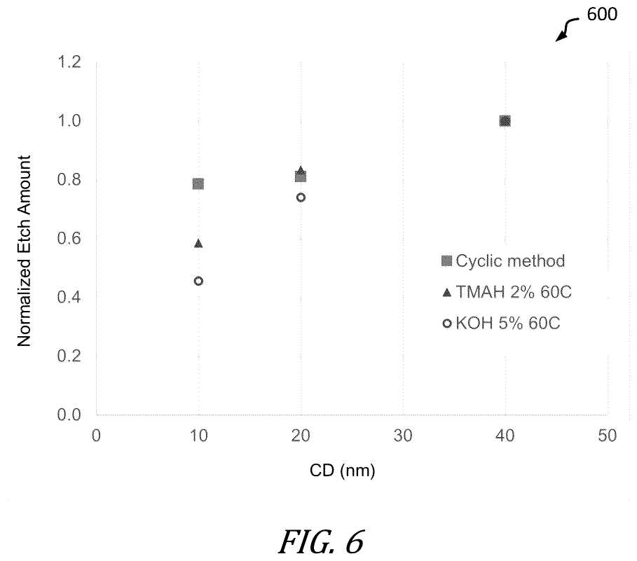

The graph 600 shown in FIG. 6 illustrates a normalized etch amount vs nano-slit CD (expressed in nm) when a cyclic process 500, as shown in FIGS. 5A-5D and described above, is used to etch amorphous silicon (a-Si) nano-slits of varying CD formed adjacent to a silicon carbon nitride (SiCN) wall material. The graph 600 shows that the normalized etch amount is relatively constant across a-Si nano-slits of 10 nm, 20 nm and 40 nm when the substrate comprising the nano-slits is cyclically exposed to a first chemical solution comprising hydrogen peroxide (H₂O₂) and a second chemical solution comprising hydrofluoric acid (HF). The graph 600 further shows that the cyclic process 500 described herein provides better etch uniformity than conventional methods used to etch a-Si, such as wet etch processes using 2% TMAH or 5% KOH at 60° C.

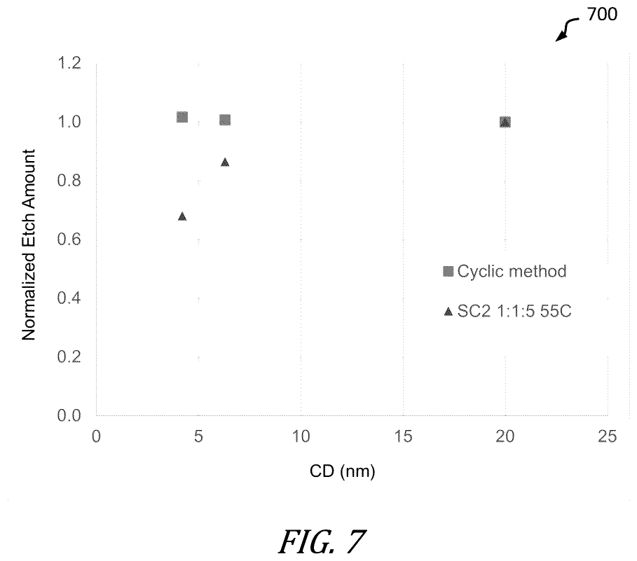

The graph 700 shown in FIG. 7 illustrates a normalized etch amount vs nano-slit CD (expressed in nm) when a cyclic process 500, as shown in FIGS. 5A-5D and described above, is used to etch titanium nitride (TiN) nano-slits of varying CD adjacent to a hafnium dioxide (HfO₂) wall material. As shown in the graph 700, the normalized etch amount is constant across TiN nano-slits of varying CD (e.g., 4, 6 and 20 nm) when the substrate comprising the nano-slits is cyclically exposed to ozone (O₃) and hydrochloric acid (HCl). The graph 700 further shows that the cyclic process 500 described herein provides significantly better etch uniformity than conventional methods used to TiN, such as a wet etch process using SC2 (1:1:5) at 55° C.

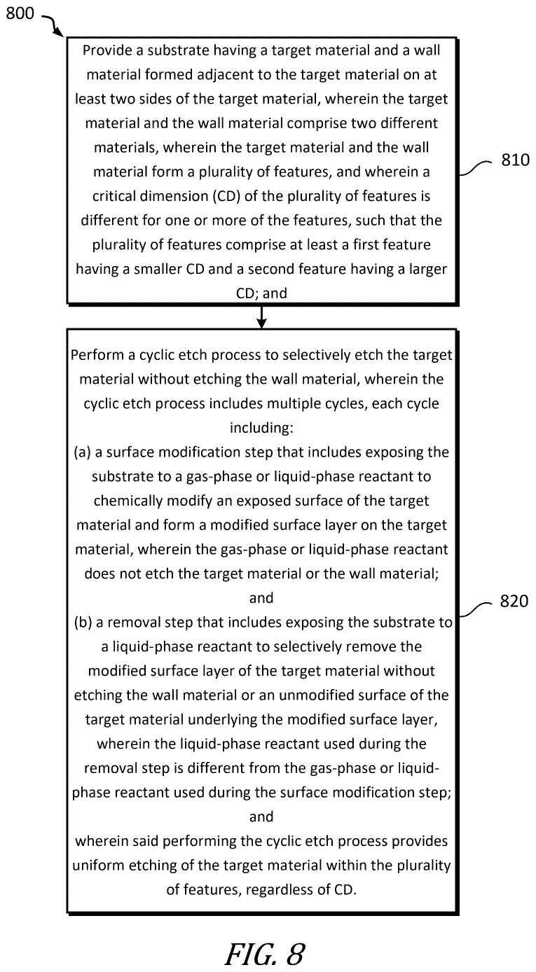

FIG. 8 illustrates another method 800 of etching that utilizes the techniques described herein to provide CD-independent etching of various target materials. It will be recognized that the method 800 shown in FIG. 8 is merely exemplary and additional methods may utilize the techniques disclosed herein. Further, additional processing steps may be added to the method 800 as the steps described are not intended to be exclusive. Moreover, the order of the steps is not limited to the order shown in the figures as different orders may occur and/or various steps may be performed in combination or at the same time.

Similar to the previous method 300 shown in FIG. 3, the method 800 shown in FIG. 8 may generally begin by providing a substrate having a target material and a wall material formed adjacent to the target material on at least two sides of the target material (in step 810). The target material and the wall material are two different materials. As depicted in the example embodiments shown in FIGS. 4A-4D and FIGS. 5A-5D, the target material and the wall material may form a plurality of features such as, for example, gaps, trenches, holes, slits, etc. A critical dimension (CD) of the plurality of features is different for one or more of the features. For example, in the embodiments disclosed herein, the plurality of features may include at least a first feature having a smaller CD and a second feature having a larger CD.

In the method 800, a cyclic process is performed (in step 820) to selectively etch the target material without etching the wall material. As shown in FIGS. 4A-4D and FIGS. 5A-5D and described above, the cyclic process includes multiple cycles, where each cycle includes: (a) a surface modification step that includes exposing the substrate to a gas-phase or liquid-phase reactant to chemically modify an exposed surface of the target material and form a modified surface layer on the target material, wherein the gas-phase or liquid-phase reactant does not etch the target material or the wall material; and (b) a removal step that includes exposing the substrate to a liquid-phase reactant to selectively remove the modified surface layer of the target material without etching the wall material or an unmodified surface of the target material underlying the modified surface layer, wherein the liquid-phase reactant used during the removal step is different from the gas-phase or liquid-phase reactant used during the surface modification step. In doing so, the cyclic process performed in step 820 provides uniform etching of the target material within the plurality of features, regardless of CD.

Processes and methods to provide uniform etching of material within features of different CD formed on a substrate are described in various embodiments. The substrate may include any material portion or structure of a device, particularly a semiconductor or other electronics device, and may, for example, be a base substrate structure, such as a semiconductor substrate or a layer on or overlying a base substrate structure such as a thin film. Thus, the term “substrate” is not intended to be limited to any particular base structure, underlying layer or overlying layer, patterned or unpatterned, but rather, is contemplated to include any such layer or base structure, and any combination of layers and/or base structures.

The term “substrate” as used herein means and includes a base material or construction upon which materials are formed. It will be appreciated that the substrate may include a single material, a plurality of layers of different materials, a layer or layers having regions of different materials or different structures in them, etc. These materials may include semiconductors, insulators, conductors, or combinations thereof. For example, the substrate may be a semiconductor substrate, a base semiconductor layer on a supporting structure, a metal electrode or a semiconductor substrate having one or more layers, structures, features or regions formed thereon. The substrate may be a conventional silicon substrate or other bulk substrate comprising a layer of semi-conductive material. As used herein, the term “bulk substrate” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

It is noted that reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

One skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Further modifications and alternative embodiments of the described wet etch processes and methods will be apparent to those skilled in the art in view of this description. It will be recognized, therefore, that the described etch processes and methods are not limited by the examples described herein. It is to be understood that the forms of the processes and methods herein shown and described are to be taken as example embodiments. Various changes may be made in the implementations. Thus, although the inventions are described herein with reference to specific embodiments, various modifications and changes can be made without departing from the scope of the present inventions. Accordingly, the specification and figures are to be regarded in an illustrative rather than a restrictive sense, and such modifications are intended to be included within the scope of the present inventions. Further, any benefits, advantages, or solutions to problems that are described herein with regard to specific embodiments are not intended to be construed as a critical, required, or essential feature or element of any or all the claims.

What is claimed is:

1. A method of etching, comprising:
providing a substrate having a target material and a wall material formed adjacent to the target material on at least two sides of the target material, wherein the target material and the wall material comprise two different materials, wherein the target material and the wall material form a plurality of features, and wherein a critical dimension (CD) of the plurality of features is different for one or more of the features, such that the plurality of features comprise at least a first feature having a smaller CD and a second feature having a larger CD; and
selectively etching the target material within the plurality of features, the selectively etching including exposing the substrate to a plurality of different reactants in series to: (a) chemically modify an exposed surface of the target material by exposing the exposed surface of the target material to a gas-phase or liquid-phase reactant to form a modified surface layer having a self-limiting thickness, and (b) selectively remove the modified surface layer by exposing the modified surface layer to a chemical solution comprising a reactant, which differs from the gas-phase or liquid-phase reactant;
wherein the chemical modification of the exposed surface of the target material and the selective removal of the modified surface layer provides uniform etching of the target material within the plurality of features, regardless of CD; and
wherein the chemical modification of the exposed surface of the target material and the selective removal of the modified surface layer are sequentially and alternatingly performed a plurality of times to selectively etch a desired amount of the target material.

2. The method of claim 1, wherein the plurality of features comprise a plurality of trenches or holes, which are formed within the wall material and filled with the target material, and wherein said exposing the substrate to the plurality of different reactants in series provides uniform vertical etching of the target material within the plurality of trenches or holes, regardless of CD.

3. The method of claim 1, wherein the plurality of features comprise a plurality of nano-slits, which are formed within the wall material and filled with the target material, and wherein said exposing the substrate to the plurality of different reactants in series provides uniform horizontal etching of the target material within the plurality of nano-slits, regardless of CD.

4. The method of claim 1, wherein the target material comprises one or more of silicon, a metal, an oxide and a nitride, and wherein the wall material comprises a dielectric material.

5. The method of claim 4, wherein the gas-phase or liquid-phase reactant used to chemically modify the exposed surface of the target material is an oxidizing agent, and wherein the oxidizing agent oxidizes the exposed surface of the target material to form an oxidized surface layer, which is selectively removed by the chemical solution.

6. The method of claim 5, wherein the oxidizing agent is a liquid-phase oxidizing agent, and wherein the liquid-phase oxidizing agent is hydrogen peroxide (H₂O₂), a sulfuric peroxide mixture (SPM), a standard clean 1 (SC1) mixture, a standard clean 2 (SC2) mixture, nitric acid (HNO₃), sulfuric acid (H₂SO₄), ammonium persulfate (APS), ferric chloride (FeCl₃), ozone (O₃) dissolved in water, or oxygen (O₂) dissolved in water.

7. The method of claim 5, wherein the oxidizing agent is a gas-phase oxidizing agent, and wherein the gas-phase oxidizing agent is ozone (O₃), oxygen (O₂), nitrogen dioxide (NO₂) or nitrous oxide (N₂O).

8. The method of claim 5, wherein the chemical solution used to selectively remove the oxidized surface layer comprises one or more of an acid, a base, an aqueous solvent, an organic solvent and a ligand.

9. The method of claim 1, wherein the target material is amorphous silicon (a-Si), wherein the wall material is silicon carbon nitride (SiCN), wherein the gas-phase or liquid-phase reactant is hydrogen peroxide (H₂O₂), and wherein the chemical solution comprises hydrofluoric acid (HF).

10. The method of claim 1, wherein the target material is titanium nitride (TiN), wherein the wall material is hafnium dioxide (HfO₂), wherein the gas-phase or liquid-phase reactant is ozone (O₃) gas, and wherein the chemical solution comprises hydrochloric acid (HCl).

11. A method of etching, the method comprising:
providing a substrate having a target material and a wall material formed adjacent to the target material on at least two sides of the target material, wherein the target material and the wall material comprise two different materials, wherein the target material and the wall material form a plurality of features, and wherein a critical dimension (CD) of the plurality of features is different for one or more of the features, such that the plurality of features comprise at least a first feature having a smaller CD and a second feature having a larger CD; and
performing a cyclic process to selectively etch the target material without etching the wall material, wherein the cyclic process includes multiple cycles, each cycle including:
(a) a surface modification step that includes exposing the substrate to a gas-phase or liquid-phase reactant to chemically modify an exposed surface of the target material and form a modified surface layer on the target material, wherein the gas-phase or liquid-phase reactant does not etch the target material or the wall material; and
(b) a removal step that includes exposing the substrate to a liquid-phase reactant to selectively remove the modified surface layer of the target material without etching the wall material or an unmodified surface of the target material underlying the modified surface layer, wherein the liquid-phase reactant used during the removal step is different from the gas-phase or liquid-phase reactant used during the surface modification step; and
wherein said performing the cyclic process provides uniform etching of the target material within the plurality of features, regardless of CD.

12. The method of claim 11, wherein the plurality of features comprise a plurality of trenches or holes, which are formed within the wall material and filled with the target material, and wherein said performing the cyclic process provides uniform vertical etching of the target material within the plurality of trenches or holes, regardless of CD.

13. The method of claim 11, wherein the plurality of features comprise a plurality of nano-slits, which are formed within the wall material and filled with the target material, and wherein said performing the cyclic process provides uniform horizontal etching of the target material within the plurality of nano-slits, regardless of CD.

14. The method of claim 11, wherein the target material comprises one or more of silicon, a metal, an oxide and a nitride, and wherein the wall material comprises a dielectric material.

15. The method of claim 14, wherein the gas-phase or liquid-phase reactant used during the surface modification step is an oxidizing agent, wherein the oxidizing agent oxidizes the exposed surface of the target material to form an oxidized surface layer, which is selectively removed by the liquid-phase reactant used during the removal step.

16. The method of claim 15, wherein the oxidizing agent is a liquid-phase oxidizing agent, and wherein the liquid-phase oxidizing agent is hydrogen peroxide (H₂O₂), a sulfuric peroxide mixture (SPM), a standard clean 1 (SC1) mixture, a standard clean 2 (SC2) mixture, nitric acid (HNO₃), sulfuric acid (H₂SO₄), ammonium persulfate (APS), ferric chloride (FeCl₃), ozone (O₃) dissolved in water, or oxygen (O₂) dissolved in water.

17. The method of claim 15, wherein the oxidizing agent is a gas-phase oxidizing agent, and wherein the gas-phase oxidizing agent is ozone (O₃), oxygen (O₂), nitrogen dioxide (NO₂) or nitrous oxide (N₂O).

18. The method of claim 17, wherein the gas-phase or liquid-phase reactant is a halogenating agent, and wherein the halogenating agent halogenates the exposed surface of the target material to form a halogenated surface layer, which is selectively removed by the liquid-phase reactant used during the removal step.

19. The method of claim 18, wherein the halogenating agent is a chlorinating agent, a brominating agent or a fluorinating agent.

20. The method of claim 11, wherein the liquid-phase reactant used during the removal step comprises one or more of an acid, a base, an aqueous solvent, an organic solvent and a ligand.
